(19) United States
(12) Patent Application Publication
(10) Pub. No.: US 2012/0175243 A1
(43) Pub. Date: Jul. 12, 2012

(54) Method of producing a perpendicular magnetic recording medium

(75) Inventors: Motoi Fukuura, Tokyo (JP); Takashi Koike, Tokyo (JP); Shigeaki Furugoori, Tokyo (JP); Masaki Uemura, Tokyo (JP)

(73) Assignee: WD MEDIA (SINGAPORE) PTE. LTD., Irvine, CA (US)

(21) Appl. No.: 13/166,023

(22) Filed: Jun. 22, 2011

(30) Foreign Application Priority Data
Jun. 22, 2010 (JP) 2010-141844

(51) Int. Cl. C23C 14/34

(52) U.S. Cl. 204/192.1

(57) ABSTRACT

To provide a method for manufacturing a perpendicular magnetic recording medium which has improved electromagnetic conversion characteristics, and thus making it possible to achieve the much higher recording density.

Disclosed is a method for manufacturing a perpendicular magnetic recording medium to be used for recording information by a perpendicular magnetic recording system, the perpendicular magnetic recording medium including at least a soft magnetic layer, an underlayer, and a magnetic recording layer on a substrate. In the method, the underlayer is formed by sputtering deposition, including a low-gas-pressure deposited layer deposited at a low gas pressure during the deposition, and a high-gas-pressure deposited layer deposited at a high gas pressure during the deposition. The high-gas-pressure deposited layer is formed of a multilayer deposited by decreasing a deposition rate in a stepwise manner.

### BACKGROUND OF THE INVENTION

1. Technical Field

The present invention relates to a method for manufacturing a perpendicular magnetic recording medium to be mounted on a magnetic disk device of a perpendicular magnetic recording system, such as a hard disk drive (HDD).

2. Background Art

With increasing capacity for information processing, various types of information recording techniques have been recently developed. In particular, the HDD using a magnetic recording technique has been continuing to increase a surface recording density at a rate of about 100% per year. In recent years, magnetic disks of 2.5 inches in diameter for use in the HDD or the like have been required to have an information recording capacity exceeding 250 Gbyte per piece. An information recording density exceeding 400 Gbit per square inch is required so as to achieve such a requirement. In order to achieve the high recording density in the magnetic disk to be used in the HDD or the like, it is necessary to miniaturize magnetic crystal particles included in a magnetic recording layer for recording information signals, and to decrease the thickness of the magnetic recording layer. However, in a magnetic disk for an in-plane magnetic recording system (which is also referred to as a longitudinal magnetic recording system, or a horizontal magnetic recording system) commercialized in the related art, progress in reducing the size of the magnetic crystal particles would result in degradation of the thermal stability of the recording signals due to a superparamagnetic phenomenon. This generates a thermal fluctuation phenomenon causing the recording signal to disappear, which interrupts an increase in recording density of the magnetic disk.

In order to solve such a cause for interruption, magnetic disks for the perpendicular magnetic recording system have been recently proposed. Unlike the in-plane magnetic recording system, in the case of the perpendicular magnetic recording system, the magnetization easy axis of the magnetic recording layer is adjusted to be directed perpendicularly with respect to the surface of the substrate. The perpendicular magnetic recording system can suppress the thermal fluctuation phenomenon as compared to the in-plane magnetic recording system, and hence is suitable for achieving the higher recording density. For example, Japanese Unexamined Patent Publication No. 2002-92865 discloses a technique regarding a perpendicular magnetic recording medium including a soft magnetic layer, an underlayer, a Co-based perpendicular magnetic recording layer, a protective layer, and the like which are formed on a substrate in that order. Further, U.S. Pat. No. 6,468,670 specification discloses a perpendicular magnetic recording medium which has a structure with a continuous layer of an artificial lattice film (exchange coupled layer) exchange-coupled to a particulate recording layer.

Currently, the perpendicular magnetic recording media have been required to have a higher recording density.

The perpendicular magnetic recording medium includes, as main components, a magnetic recording layer formed of hard magnetic material, a soft magnetic (backing) layer formed of soft magnetic material, and an intermediate layer or the like formed of non-magnetic material positioned between the magnetic recording layer and the soft magnetic layer. Any one of these layers has a multilayered structure at present.

Among these layers, the intermediate layer is located under the magnetic recording layer and is a portion serving to control a crystal orientation of the magnetic recording layer and the isolation of a granular structure. In short, the intermediate layer is a very important part as it serves as a base for the magnetic recording layer. Thus, the structure, material, and deposition process of the perpendicular magnetic recording media, and the like have been strenuously studied and developed. As a result, the intermediate layer is divided into a seed layer positioned on the lower side and an underlayer positioned on the upper side. The underlayer includes a lamination of a lower underlayer deposited in a process at a low gas pressure, and an upper underlayer deposited in another process at a high gas pressure, using the same material. In particular, the upper underlayer deposited at the high gas pressure is positioned directly under the granular magnetic recording layer, and thus is a very important part from the viewpoint of controlling magnetic characteristics.

### CITATION LIST

### Patent Literature

Patent Literature 1: Japanese Unexamined Patent Publication No. 2002-92865
Patent Literature 2: U.S. Pat. No. 6,468,670 specification

The present inventors have made progress in study and found that the simple laminated structure comprised of the lower underlayer deposited in the process at the low gas pressure, and the upper underlayer deposited at the high gas pressure in the related art cannot provide desired electromagnetic conversion characteristics for a magnetic recording medium having a higher recording density.

As can be seen from the consideration made by the present inventors, the reason for this is that the upper underlayer deposited in the process at the high gas pressure has a granular structure itself, but uniformity and isolation of particles and grain boundary is insufficient. Thus, the upper underlayer also affects the granular structure of the magnetic recording layer located directly above the upper underlayer, which results in degradation of the ratio S/N (signal/noise) at the time of recording and reproducing.

### SUMMARY OF THE INVENTION

Under the conventional circumstances, an object of the present invention is to provide a method for manufacturing a perpendicular magnetic recording medium, which can improve the electromagnetic conversion characteristics to achieve the higher recording density.

The present inventors have studied and found that the lower underlayer mainly contributing to the crystal orientation of a magnetic layer has a relatively small effect of improving the electromagnetic conversion characteristics by changing the deposition rate, whereas the upper underlayer mainly contributing to the isolation of the magnetic layer improves the electromagnetic conversion characteristics by reducing (decreasing) the deposition rate. In sputtering deposition, the deposition at a high rate causes sputtered particles with thermal energy to reach the substrate and then to migrate on the substrate to thereby form a film with high crystallinity which hardly has lattice defects, and which is stabilized from the viewpoint of energy. In contrast, the deposition at a low rate causes sputtered particles to reach the substrate and then to remain on site to thereby form a sparse film. Thus, it is considered that the upper underlayer for achieving the isolation is deposited at a power lower than the normal power, that is, at a low rate, whereby sputtered particles are separated from each other and the isolation of magnetic particles growing thereon is promoted to thus form the underlayer with the excellent electromagnetic conversion characteristics. When the upper underlayer is deposited at the low rate so as to improve the electromagnetic conversion characteristics, the time of deposition is extended by the time corresponding to the deposition, which leads to reduction in manufacturing tact (quantity of products produced in a certain time). Thus, this deposition is not appropriate for commercial production.

Thus, the present inventors have intensively studied and as a result found that by increasing the number of necessary chambers according to the conditions, the underlayer having a desired thickness can be obtained and the electromagnetic conversion characteristics can be improved without decreasing a tact time even during the deposition at the low rate. As a result, the present invention has been completed. That is, the present invention has the following constructions so as to achieve the above object.

First Construction

A method for manufacturing a perpendicular magnetic recording medium to be used for recording information by a perpendicular magnetic recording system, the perpendicular magnetic recording medium including at least a soft magnetic layer, an underlayer, and a magnetic recording layer on a substrate, the method comprising the step of forming the underlayer including a low-gas-pressure deposited layer and a high-gas-pressure deposited layer through sputtering deposition by depositing the low-gas-pressure deposited layer at a low gas pressure of less than 1.0 Pa during the deposition, and depositing the high-gas-pressure deposited layer at a high gas pressure of 1.0 Pa or more during the deposition, wherein the high-gas-pressure deposited layer is formed of a multilayer deposited by decreasing a deposition rate in a stepwise manner.

Second Construction

In the method for manufacturing the perpendicular magnetic recording medium according to the first construction, the high-gas-pressure deposited layer is deposited using a plurality of chambers.

Third Construction

In the method for manufacturing the perpendicular magnetic recording medium according to the first or second construction, the underlayer is deposited using three chambers, the method further including the steps of performing the deposition by setting the gas pressure in the deposition to the low gas pressure in a first chamber; performing the deposition by setting the gas pressure in the deposition to the high gas pressure in a second chamber; and performing the deposition by setting the gas pressure in the deposition to the high gas pressure, at a deposition rate lower than that in the second chamber, in a third chamber.

Fourth Construction

In the method for manufacturing the perpendicular magnetic recording medium according to any one of the first to third constructions, the deposition rate for the uppermost layer among the high-gas-pressure deposited layers is 1.6 nm/second or less.

Fifth Construction

In the method for manufacturing the perpendicular magnetic recording medium according to any one of the first to fourth constructions, the underlayer includes material containing Ru or an alloy thereof as a main component.

According to the invention, the underlayer is formed by sputtering deposition, and includes a low-gas-pressure deposited layer deposited at a low gas pressure during the deposition and a high-gas-pressure deposited layer deposited at a high gas pressure during the deposition. The high-gas-pressure deposited layer is formed of a multilayer deposited by decreasing a deposition rate in a stepwise manner. This arrangement improves the perpendicular orientation and the crystal isolation property due to the miniaturization of the underlayer directly below the magnetic recording layer, and thus can improve the electromagnetic conversion characteristics of the magnetic recording layer. Accordingly, the perpendicular magnetic recording medium can be provided which achieves the much higher recording density.

### BRIEF DESCRIPTION OF THE DRAWINGS

FIG. 1 is a diagram showing the result of comparison of the electromagnetic conversion characteristics of perpendicular magnetic recording media between Example and Comparative Example; and

FIG. 2 is a diagram showing the result of comparison of the electromagnetic conversion characteristics of the perpendicular magnetic recording media between Example and Comparative Example.

### DETAILED DESCRIPTION OF THE PREFERRED EMBODIMENTS

Embodiments of the present invention will be described in detail below.

According to the first construction of the present invention, a method for manufacturing a perpendicular magnetic recording medium to be used for recording information by a perpendicular magnetic recording system is provided. The perpendicular magnetic recording medium includes at least a soft magnetic layer, an underlayer, and a magnetic recording layer on a substrate. In the method, the underlayer is formed by sputtering deposition and includes a low-gas-pressure deposited layer deposited at a low gas pressure during the deposition, and a high-gas-pressure deposited layer deposited at a high gas pressure during the deposition. The high-gas-pressure deposited layer is formed of a multilayer deposited by decreasing a deposition rate in a stepwise manner.

Specifically, the layer structure of the perpendicular magnetic recording medium in one embodiment of the present invention is a lamination of, for example, an adhesive layer, a soft magnetic layer, a seed layer, an underlayer, a magnetic recording layer (perpendicular magnetic recording layer), a protective layer, a lubricating layer, and the like, which are laminated from the side close to the substrate.

The underlayer is used for suitably controlling the crystal orientation (which causes the crystal orientation to be directed perpendicularly with respect to the substrate surface) of the perpendicular magnetic recording layer, the crystal grain size, and the grain boundary segregation of the perpendicular magnetic recording layer. The underlayer is preferably formed of an elementary substance or an alloy thereof which has a face-centered cubic (fcc) structure or a hexagonal closest packing (hcp) structure. Examples of suitable materials for the underlayer include, but are not limited to, Ru, Pd, Pt, Ti, and an alloy containing at least one of them. In the present invention, particularly, Ru or an alloy thereof is preferably used. The Ru is suitable for controlling the crystal axis (c axis) of a CoPt-based perpendicular magnetic recording layer having a hcp crystal structure in the perpendicular direction. In the case of a laminated structure formed by the process at the low gas pressure and by the process at the high gas pressure, the combination of different kinds of materials instead of the same material can also be used.

In the present invention, an underlayer deposition step have conventionally involved one deposition process at a low gas pressure in a first chamber, and another deposition process at a high gas pressure in a second chamber to thereby form two underlayers by sputtering. However, in the present invention, the above deposition processes were replaced by the following processes.

a. First, a gas pressure for deposition is set to a low level, and then a low-gas-pressure deposited layer is formed at the set low gas pressure.

b. Then, a next gas pressure for deposition is set to a high level, and then a high-gas-pressure deposited layer is deposited at the set high gas pressure. The deposited layer at the high gas pressure is comprised of a multilayer deposited using a plurality of chambers by decreasing the deposition rate in a stepwise manner.

As mentioned above, the inventors have found through their studies that for example, by decreasing the deposition rate of a Ru layer in the deposition process at the high gas pressure, the characteristics of the perpendicular magnetic recording medium is greatly improved. Further, by decreasing the deposition rate of the Ru layer in the deposition process at the low gas pressure, the characteristics of the recording medium is also improved. In particular, in the high-gas-pressure deposition process, the effect of improving the characteristics produced by decreasing the deposition rate of the Ru layer is very large. However, for example, when only the deposition rate of the Ru layer in the high-gas pressure deposition process is simply decreased, it takes much longer to deposit the underlayer, which reduces the manufacturing takt. Normally, the time of deposition in one chamber is set to a predetermined time. For this reason, the high-gas-pressure deposition process is performed using the plurality of chambers to deposit the multilayer by decreasing the deposition rate in a stepwise manner every chamber.

That is, in the present invention, the deposition rate in the high-gas-pressure process performed as a multilayer deposition process can be appropriately decreased using the same or similar material (metal elementary substance or an alloy thereof) as the material for the underlayer. In other words, for example, the deposition time of the Ru layer at the high gas pressure can be extended to thereby improve the characteristics of the recording medium.

In one preferred embodiment of the present invention, the deposition of the underlayer is performed using three chambers. First, in a first chamber, a gas pressure for the deposition is set to a low level, and then the deposition is performed at the set low gas pressure. Thereafter, in each of the second and third chambers, a gas pressure for the deposition is set to a corresponding high level, and a deposition power is set lower than the normal (present) deposition power, so that the deposition is performed at a deposition rate lower than the normal (present) deposition rate.

The deposition rate of the high-gas-pressure deposited layer differs depending on the setting of the takt time, but is preferably, for example, 1.6 nm/second or less so as to effectively improve the electromagnetic conversion characteristics. For example, when the two high-gas-pressure deposited layers are intended to be deposited in a thickness of about 10 nm in total while keeping the takt time at 1200 pph, the deposition is preferably performed at a deposition rate of 1.6 nm/second or less.

The present invention optimizes the deposition process of the upper underlayer, which is deposited at a high gas pressure in the related art, as mentioned above, which can improve the uniformity and isolation of the granular structure of the upper underlayer directly under the magnetic recording layer. As a result, the electromagnetic conversion characteristics of the magnetic recording layer can be further improved.

In the present invention, the low gas pressure in depositing the underlayer is preferably set to, for example, less than 1.0 Pa, and the high gas pressure is set to, for example, 1.0 Pa or more.

There is no particular limitation on the thickness of the underlayer, but the thickness is desirably set to the minimum thickness required to control the structure of the perpendicular magnetic recording layer, for example, to about 5 to 50 nm in total.

The soft magnetic layer is preferably provided on the substrate so as to appropriately adjust a magnetic circuit of the perpendicular magnetic recording layer. Such a soft magnetic layer is preferably comprised of a first soft magnetic layer, a second soft magnetic layer, and a non-magnetic spacer layer intervening in between the first and second soft magnetic layers to thus achieve antiferro-magnetic exchange coupling (AFC). Thus, the magnetization directions of the first soft magnetic layer and of the second soft magnetic layer can be set anti-parallel to each other with high accuracy, which can reduce noise generated from the soft magnetic layer. Specifically, a suitable composition for each of the first soft magnetic layer and the second soft magnetic layer can be, for example, CoTaZr (cobalt-tantalum-zirconium), CoFeTaZr (cobalt-iron-tantalum-zirconium), CoFeTaZrAlCr (cobalt-iron-tantalum-zirconium-aluminum-chromium), or CoFeNiTaZr (cobalt-iron-nickel-tantalum-zirconium). A suitable composition for the above spacer layer can be, for example, Ru (ruthenium). The thickness of the soft magnetic layer differs depending on the structure of the soft magnetic layer, and the structure and characteristics of the magnetic head, and is preferably in a range of 15 to 100 nm in total. The thicknesses of the upper and lower layers may be slightly different from each other from the viewpoint of optimizing the recording and reproducing operations, but are desirably substantially equal to each other.

The adhesive layer is preferably formed between the substrate and the soft magnetic layer. The formation of the adhesive layer can improve the adhesion between the substrate and the soft magnetic layer to prevent peeling of the soft magnetic layer. The adhesive layer can be formed using, for example, a Ti-containing material.

The seed layer is used for controlling the orientation and crystallinity of the underlayer. The crystal growth would be degraded due to compatibility between the soft magnetic layer and the underlayer. When all layers are continuously deposited, the seed layer is not necessary in some cases. However, the use of the seed layer can prevent the degradation of the crystal growth of the underlayer. The thickness of the seed layer is desirably set to the minimum thickness required to control the crystal growth of the underlayer. The excessively thick seed layer reduces the writing capacity of signals.

Examples of the glass for the above substrate include aluminosilicate glass, aluminoborosilicate glass, soda-lime glass, and the like. Among them, the aluminosilicate glass is preferable. Further, amorphous glass or crystal glass can be used for the formation of the substrate. The use of a chemically hardened glass preferably enhances the toughness of the substrate. In the invention, the surface roughness of the main surface of the substrate is preferably as follows: Rmas is 10 nm or less, and Ra is 0.3 nm or less.

The perpendicular magnetic recording layer preferably includes a ferromagnetic layer having a granule structure which includes crystal particles mainly containing cobalt (Co), and a boundary part mainly containing Si, Ti, Cr, Co, or an oxide of Si, Ti, Cr, or Co.

Specifically, a Co-based magnetic material for forming the above ferromagnetic layer is desirably material for molding a hcp crystal structure using a hard magnetic target composed of CoCrPt (cobalt-chrome-platinum) containing at least one of silicon oxide (SiO₂) or titanium oxide (TiO₂) which is a non-magnetic material. The thickness of the ferromagnetic layer is preferably, for example, 20 nm or less.

An auxiliary recording layer can be provided above the perpendicular magnetic recording layer via an exchange-coupling control layer to achieve the high heat resistance in addition to the high recording density and the low noise of the magnetic recording layer. The composition of the auxiliary recording layer can be, for example, CoCrPtB or the like.

The exchange-coupling control layer is preferably formed between the perpendicular magnetic recording layer and the auxiliary recording layer. The provision of the exchange-coupling control layer can suitably control the strength of exchange-coupling between the perpendicular magnetic recording layer and the auxiliary recording layer to optimize the recording and reproducing characteristics. The exchange-coupling control layer is preferably formed, for example, using Ru and the like.

A formation method of the perpendicular magnetic recording layer including the above ferromagnetic layer is preferably deposited by sputtering. In particular, the use of a DC magnetron sputtering method is preferable because it enables the uniform deposition.

Preferably, the protective layer is provided on the perpendicular magnetic recording layer. The provision of the protective layer can protect the surface of the magnetic disk from the magnetic head floating above the magnetic recording medium. The protective layer is preferably formed of, for example, a carbon-based protective layer. Preferably, the thickness of the protective layer is in a range of about 3 to 7 nm.

Further, a lubricating layer is preferably provided on the protective layer. The provision of the lubricating layer can prevent abrasion between the magnetic head and the magnetic disk to improve the durability of the magnetic disk. Suitable material for the lubricating layer is, for example, perfluoro polyether (PEPE)-based compound. The lubricating layer can be formed, for example, by a dip coat method.

### EXAMPLES

Embodiments of the invention will be more specifically described below by way of Example and Comparative Example.

### Example 1

An amorphous aluminosilicate glass was molded into a disk shape by direct press to produce a glass disk. The glass disk was cut, polished, and chemically hardened in sequence, whereby a flat non-magnetic glass substrate formed of the chemically hardened glass disk was obtained. The diameter of the disk was 65 mm. The surface roughness of the main surface of the glass substrate was measured by an atomic force microscope (AFM) to obtain the following result: Rmax was 2.18 nm, and Ra was 0.18 nm. The thus-obtained substrate was found to have a flat surface. The Rmax and Ra were measured in accordance to Japanese Industrial Standards (JIS).

Then, an adhesive layer, a soft magnetic layer, a seed layer, an underlayer, a perpendicular magnetic recording layer, an exchange-coupling control layer, an auxiliary recording layer, and a protective layer were deposited on the glass substrate in that order by DC magnetron sputtering using a cluster type stationary facing sputtering device.

Numeral values in the description about the following respective materials indicate the respective compositions.

Specifically, first, a Cr-50Ti layer was deposited as the adhesive layer in the thickness of 10 nm.

Then, a laminated film of two soft magnetic layers antiferromagnetically exchange-coupled via the non-magnetic layer was deposited as the soft magnetic layer. That is, first, a (30Fe-70Co)-3Ta5Zr layer was deposited in a thickness of 25 nm as the first soft magnetic layer. Then, a Ru layer was deposited in a thickness of 0.7 nm as the non-magnetic layer. Further, another (30Fe-70Co)-3Ta5Zr layer, which was formed of the same material as the first soft magnetic layer, was deposited in a thickness of 25 nm as the second soft magnetic layer.

Subsequently, a Ni-7W layer was deposited in a thickness of 5 nm on the soft magnetic layer as the seed layer.

Then, the underlayer was deposited. That is, in a first chamber with a Ru target attached thereto, the material Ru was deposited in a thickness of 12 nm by adjusting an Ar gas pressure to 0.7 Pa and setting the power to the normal predetermined value. Subsequently, in a second chamber with the same Ru target attached thereto, the material Ru was deposited in a thickness of 6 nm at a deposition rate of 1.6 nm/second by adjusting the Ar gas pressure to 4.5 Pa and setting the power to a value lower than the normal predetermined value. Then, in a third chamber with the same Ru target attached thereto, the material Ru was deposited in a thickness of 6 nm at a deposition rate of 1.6 nm/second by adjusting the Ar gas pressure to 4.5 Pa and setting the power to a value lower than the normal predetermined value. During the deposition of the underlayer, the takt time was kept at 1200 pph.

In this way, the underlayer was formed which consists of a low-gas-pressure deposited layer of 12 nm in thickness and two high-gas-pressure deposited layers of 12 nm in thickness in total by changing the deposition rate.

Then, the magnetic recording layer was deposited on the underlayer. First, 90(Co-10Cr-16Pt)-5SiO₂-5TiO₂ was deposited in a thickness of 10 nm as the perpendicular magnetic recording layer. Then, a Ru layer was deposited in a thickness of 0.3 nm as the exchange-coupling controller, and further Co-15Cr-15Pt-5B was deposited thereon in a thickness of 7 nm as the auxiliary recording layer.

Thereafter, the carbon-based protective layer comprised of a hydrogenated diamond-like carbon was formed on the magnetic recording layer. The thickness of the carbon-based protective layer was set to 5 nm.

Subsequently, the substrate was removed from the sputtering device, and then a lubricating layer including PFPE (perfluoro polyether) was formed by the dip coat method. The thickness of the lubricating layer was set to 1 nm.

In the above manufacturing steps, the perpendicular magnetic recording medium of Example 1 was obtained.

### Comparative Example

In a deposition step of an underlayer, in the first chamber, the material Ru was deposited in a thickness of 12 nm by setting an Ar gas pressure to 0.7 Pa and setting the power to the normal predetermined value. Then, in the second chamber, the material Ru was deposited in a thickness of 12 nm at a deposition rate of about 3.0 nm/second by adjusting an Ar gas pressure to 4.5 Pa and setting the power to the normal predetermined value.

In the same manner as in Example 1, except for the deposition step of the underlayer, a perpendicular magnetic recording medium of Comparative Example was obtained.

(Evaluation)

The following evaluation was performed using the perpendicular magnetic recording media of Example and Comparative Example described above.

That is, the magnetic characteristics and the recording and reproducing characteristics of the respective perpendicular magnetic recording media of Example 1 and Comparative Example were evaluated. The evaluation of the magnetostatic characteristics was performed by measuring the coercive force (Hc), the reverse magnetic domain nucleus formation magnetic field (-Hn), and the saturated magnetic field (Hs) by use of a Kerr effect measuring equipment. The evaluation of the recording and reproducing characteristics was performed by measuring the S/N ratio (signal/noise ratio) and the squash using an R/W analyzer and the magnetic head for the perpendicular magnetic recording system. The squash becomes an index of evaluation of rate of decrease in signal due to the influence given by the adjacent track. Specifically, a new signal whose frequency was displaced by about 5% was written in the position of about 80% of the track width with respect to both sides of a previous written signal. Then, an output of a signal first written was measured and the rate of a changed amount between the signals was calculated. Further, a MWW (track width) was measured at a linear recording density of 1500 kFCI (Kilo Flux Change per inch) using a spin-stand tester including a SPT/TMR head.

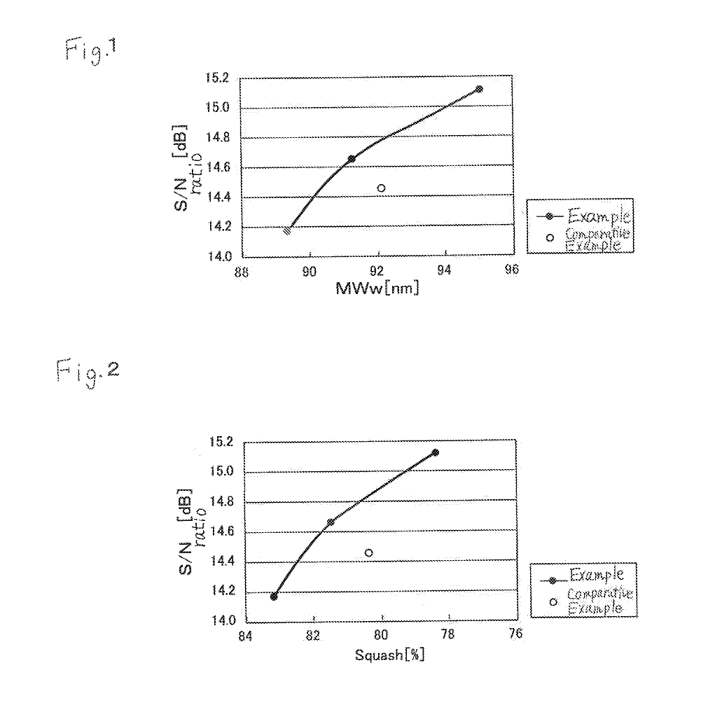

The obtained results are shown in the following Table 1, and FIGS. 1 and 2. FIG. 1 shows the relationship between the MWW (track width) and the S/N ratio, and FIG. 2 shows the relationship between the squash and the S/N ratio.

TABLE 1

| | Hc [0e] | Hn [0e] | Hs [0e] | MWW [nm] | S/N [dB] |
|---|---|---|---|---|---|
| Comparative | 5568 | −2813 | 8594 | 91 | 14.7 |
| Example | | | | | |
| Example 1 | 5448 | −2966 | 8408 | 95 | 14.8 |

From the results shown in Table 1 and FIGS. 1 and 2, the following can be confirmed. That is, the perpendicular magnetic recording medium of Example 1 has satisfactory recording and reproducing characteristics as well as the satisfactory magnetostatic characteristics as compared to Comparative Example. Thus, the perpendicular magnetic recording medium of Example 1 has the improved electromagnetic conversion characteristics, and can obtain the desired characteristics to achieve the much higher recording density.

What is claimed is:

1. A method for manufacturing a perpendicular magnetic recording medium to be used for recording information by a perpendicular magnetic recording system, the perpendicular magnetic recording medium comprising at least a soft magnetic layer, an underlayer, and a magnetic recording layer on a substrate, the method comprising the step of:
forming the underlayer including a low-gas-pressure deposited layer and a high-gas-pressure deposited layer through sputtering deposition by depositing the low-gas-pressure deposited layer at a low gas pressure of less than 1.0 Pa during the deposition, and depositing the high-gas-pressure deposited layer at a high gas pressure of 1.0 Pa or more during the deposition,
wherein the high-gas-pressure deposited layer is formed of a multilayer deposited by decreasing a deposition rate in a stepwise manner.

2. The method for manufacturing a perpendicular magnetic recording medium according to claim 1, wherein the high-gas-pressure deposited layer is deposited using a plurality of chambers.

3. The method for manufacturing a perpendicular magnetic recording medium according to claim 1 or 2, wherein the underlayer is deposited using three chambers, the method further comprising the steps of:
performing the deposition by setting the gas pressure in the deposition to the low gas pressure in a first chamber;
performing the deposition by setting the gas pressure in the deposition to the high gas pressure in a second chamber; and
performing the deposition by setting the gas pressure in the deposition to the high gas pressure, at a deposition rate lower than that in the second chamber, in a third chamber.

4. The method for manufacturing a perpendicular magnetic recording medium according to any one of claims 1 to 3, wherein the deposition rate of the high-gas-pressure deposited layer is 1.6 nm/second or less.

5. The method for manufacturing a perpendicular magnetic recording medium according to any one of claims 1 to 4, wherein the underlayer is formed of material containing Ru or an alloy thereof as a main component.
